(19) United States
(12) Patent Application Publication
(10) Pub. No.: US 2026/0143657 A1
(43) Pub. Date: May 21, 2026

(54) ELECTROMAGNETIC WAVE SHIELDING MATERIAL, ELECTRONIC COMPONENT, AND ELECTRONIC APPARATUS

(71) Applicant: FUJIFILM Corporation, Tokyo (JP)

(72) Inventor: Jumpei ISHIDA, Minamiashigara-shi (JP)

(73) Assignee: FUJIFILM Corporation, Tokyo (JP)

(21) Appl. No.: 19/446,266

(22) Filed: Jan. 12, 2026

Related U.S. Application Data
(63) Continuation of application No. PCT/JP2024/025595, filed on Jul. 17, 2024.

(30) Foreign Application Priority Data
Jul. 24, 2023 (JP) 2023-119674

(51) Int. Cl. H05K 9/00; B32B 7/12; B32B 15/08; B32B 15/20; B32B 27/20

(52) U.S. Cl. CPC H05K 9/0083; B32B 7/12; B32B 15/08; B32B 15/20; B32B 27/20; B32B 2250/05; B32B 2250/40; B32B 2307/208; B32B 2307/212; B32B 2307/7375

(57) ABSTRACT

Provided are an electromagnetic wave shielding material having a magnetic layer containing magnetic particles, in which a scratch cross-sectional area of the magnetic layer is 0.08 μm² or more and 1.25 μm² or less, and an electronic component and an electronic apparatus which include the electromagnetic wave shielding material.

### CROSS-REFERENCE TO RELATED APPLICATIONS

This application is a Continuation of PCT International Application No. PCT/JP2024/025595 filed on Jul. 17, 2024, which claims priority under 35 U.S.C. § 119 (a) to Japanese Patent Application No. 2023-119674 filed on Jul. 24, 2023. Each of the above applications is hereby expressly incorporated by reference, in its entirety, into the present application.

### BACKGROUND OF THE INVENTION

### 1. Field of the Invention

The present invention relates to an electromagnetic wave shielding material, an electronic component, and an electronic apparatus.

### 2. Description of the Related Art

In recent years, an electromagnetic wave shielding material has attracted attention as a material for reducing the influence of an electromagnetic wave in various electronic components and various electronic apparatuses. For example, JP2018-129498A discloses a component mounting substrate coated with an electromagnetic wave shielding material (in JP2018-129498A, “electromagnetic wave shielding layer”) containing magnetic particles (see paragraph 0109 and Table 1 of JP2018-129498A).

### SUMMARY OF THE INVENTION

An electromagnetic wave shielding material is capable of exhibiting the performance of shielding electromagnetic waves (hereinafter, also referred to as “electromagnetic wave shielding performance” or “shielding performance”) by reflecting electromagnetic waves incident on the electromagnetic wave shielding material by the electromagnetic wave shielding material and/or by attenuating the electromagnetic waves inside the electromagnetic wave shielding material.

As a usage form of the electromagnetic wave shielding material, there may be a usage form in which the electromagnetic wave shielding material is incorporated into an electronic component or an electronic apparatus and then is subjected to vibration. Therefore, it is desired that the electromagnetic wave shielding material has a small decrease in the shielding performance after being subjected to the vibration.

In consideration of the above circumstances, an object of an aspect according to the present invention is to provide an electromagnetic wave shielding material in which a decrease in electromagnetic wave shielding performance after being subjected to vibration is suppressed.

An aspect of the present invention is as follows.
[1] An electromagnetic wave shielding material comprising:
a magnetic layer containing magnetic particles,
in which a scratch cross-sectional area of the magnetic layer is 0.08 μm² or more and 1.25 μm² or less.
[2] The electromagnetic wave shielding material according to [1],
in which the magnetic layer is provided between two metal layers.
[3] The electromagnetic wave shielding material according to [2], further comprising:
one or more layers containing a resin, provided between the magnetic layer sandwiched between the two metal layers and one or both of the two metal layers.
[4] The electromagnetic wave shielding material according to any one of [1] to [3],
in which the magnetic layer further contains a resin.
[5] The electromagnetic wave shielding material according to any one of [1] to [4],
in which the scratch cross-sectional area of the magnetic layer is 0.10 μm² or more and 1.00 μm² or less.
[6] The electromagnetic wave shielding material according to any one of [1] to [5],
in which the magnetic layer is provided between two metal layers,
the magnetic layer further contains a resin, and
the scratch cross-sectional area of the magnetic layer is 0.10 μm² or more and 1.00 μm² or less.
[7] The electromagnetic wave shielding material according to [6], further comprising:
one or more layers containing a resin, provided between the magnetic layer sandwiched between the two metal layers and one or both of the two metal layers.
[8] An electronic component comprising:
the electromagnetic wave shielding material according to any one of [1] to [7].
[9] An electronic apparatus comprising:
the electromagnetic wave shielding material according to any one of [1] to [7].

According to one aspect according to the present invention, it is possible to provide the electromagnetic wave shielding material in which the decrease in the electromagnetic wave shielding performance after being subjected to the vibration is suppressed. In addition, according to one aspect of the present invention, it is possible to provide an electronic component and an electronic apparatus, which include the electromagnetic wave shielding material.

### BRIEF DESCRIPTION OF THE DRAWINGS

FIGS. 1A and 1B are explanatory views of a shape measurement of a magnetic layer cross section.

FIG. 2 is a schematic diagram showing a load change during a scratch operation.

FIG. 3 is a schematic diagram of a magnetic layer cross section on which a scratch is formed by the scratch operation.

FIG. 4 is a schematic diagram of a difference image.

FIGS. 5A to 5C are schematic diagrams for describing test conditions.

FIG. 6 is an example of a cross-sectional curve.

FIG. 7 is a schematic cross-sectional view of a laminate having a multilayer structure, which is included in an electromagnetic wave shielding material of Example 1.

FIG. 8 is a schematic cross-sectional view of the electromagnetic wave shielding material of Example 1.

FIG. 9 is an explanatory view of a measuring method for thermal conductivity.

### DESCRIPTION OF THE PREFERRED EMBODIMENTS

In the present invention and the present specification, the “electromagnetic wave shielding material” shall refer to a material that is capable of exhibiting shielding performance against an electromagnetic wave of at least one frequency or at least a part of a range of a frequency band. The “electromagnetic wave” includes a magnetic field wave and an electric field wave. The “electromagnetic wave shielding material” can be a material that is capable of exhibiting shielding performance against one or both of a magnetic field wave of at least one frequency or at least a part of a range of a frequency band and an electric field wave of at least one frequency or at least a part of a range of a frequency band.

The thickness of each layer included in the electromagnetic wave shielding material, which will be described later, and the thickness of the coating material, which will be described later, can be determined by imaging a cross section exposed by a known method with a scanning electron microscope (SEM) and determining an arithmetic average of thicknesses of five randomly selected points in the obtained SEM image.

### [Electromagnetic Wave Shielding Material]

An aspect of the present invention relates to an electromagnetic wave shielding material having a magnetic layer containing magnetic particles, in which a scratch cross-sectional area of the magnetic layer is 0.08 μm² or more and 1.25 μm² or less.

The inventors of the present invention have considered that the decrease in shielding performance of the electromagnetic wave shielding material after being subjected to vibration can be suppressed by suppressing the occurrence of a fine local fracture in the magnetic layer while the electromagnetic wave shielding material is subjected to vibration. In this regard, it is presumed that, in a case where a coarse void is present in the magnetic layer, a fine local fracture may occur in the magnetic layer with the void as a starting point. On the other hand, the inventors of the present invention have considered that such a coarse void is less likely to be present or is not included in the magnetic layer having a scratch cross-sectional area of 1.25 μm² or less. In addition, it is presumed that, even in a magnetic layer in which a fine local fracture with a coarse void as a starting point is unlikely to occur, in a case where a portion in which the magnetic particles are too close to each other is present in the magnetic layer, a fine local fracture may occur in the magnetic layer due to interference between the magnetic particles while the electromagnetic wave shielding material is subjected to vibration. On the other hand, the inventors of the present invention have considered that, in the magnetic layer having a scratch cross-sectional area of 0.08 μm² or more, the magnetic particles are appropriately spaced from each other, and thus the interference between the magnetic particles is unlikely to occur.

However, the present invention is not limited to the speculation described in the present specification.

### <Scratch Cross-Sectional Area of Magnetic Layer>

The “scratch cross-sectional area” of the magnetic layer in the present invention and the present specification is obtained by the following method.

### (1) Production of Cross-Section Exposed Specimen

An electromagnetic wave shielding material cut out to a size of 3 mm×3 mm is embedded in a resin, and a cross section of the electromagnetic wave shielding material including a cross section in a thickness direction of the magnetic layer is cut out with an ion milling device. As the ion milling device, IM4000PLUS manufactured by Hitachi High-Tech Corporation can be used. In this way, three cross-section exposed specimens are produced from the electromagnetic wave shielding material to be measured.

### (2) Shape Measurement of Magnetic Layer Cross Section Before Scratch Operation

For each of the three cross-section exposed specimens produced in (1) above, the shape of the magnetic layer cross section exposed to the specimen before the scratch operation is measured by a nanoindentation method. As a measuring device for performing the measurement by the nanoindentation method, TriboIndenter TI-950 manufactured by Bruker Corporation can be used. An identical diamond Berkovich indenter is used for the measurement of the magnetic layer cross-sectional shape and the scratch operation described later. A position at which the indenter is brought into contact with the exposed magnetic layer cross section is any position in a width direction of the magnetic layer within a range in which the cross section can be exposed by the ion milling device, and is in a vicinity of a center of the magnetic layer in the thickness direction of the magnetic layer. The magnetic layer cross section is brought into contact with the indenter under a vertical load of 1 μN, and the indenter is scanned in a range of 15.0 μm×15.0 μm to measure the shape of the magnetic layer cross section. The number of measurement lines is 256, the number of data points per line is 256, and the scanning frequency of each line is 0.5 Hz. Hereinafter, a direction of each measurement line is referred to as a “left-right direction”, and a direction orthogonal to the direction of the measurement line is referred to as an “up-down direction”.

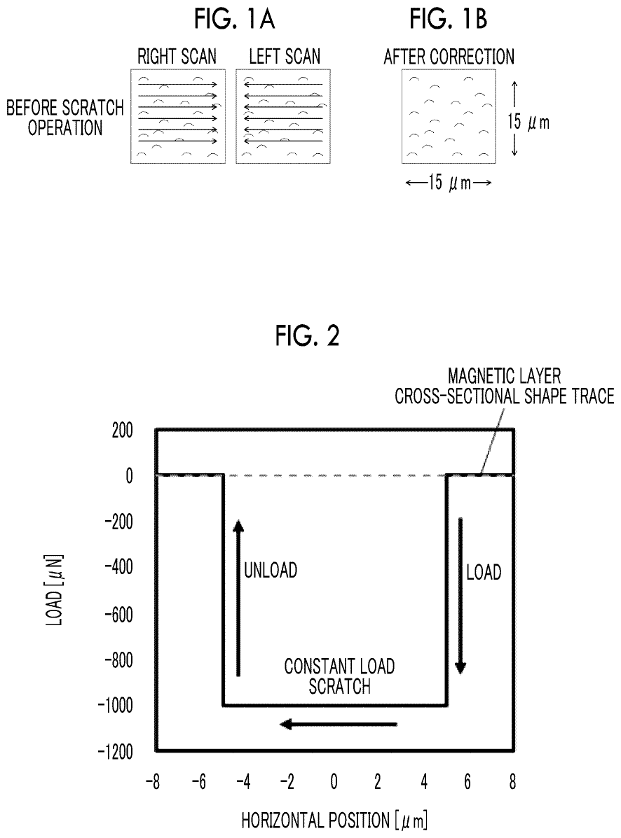

FIGS. 1A and 1B are explanatory views of a shape measurement of a magnetic layer cross section. In the shape measurement of the magnetic layer cross section, for example, as shown in FIG. 1A, both a height image (hereinafter, referred to as a “right-scan image”) in a case of scanning (right scan) in a right direction on the measurement line and a height image (hereinafter, referred to as a “left-scan image”) in a case of scanning (left scan) in a left direction are acquired. FIG. 1A is a view of the magnetic layer cross section as viewed from a direction perpendicular to the cross section, and left and right views of FIG. 1A show a case of right scan and a case of left scan of the same region, respectively. Using image analysis software, an image (hereinafter, referred to as a “corrected image”) in which the smaller height value is employed by comparing the height values of the right-scan image and the left-scan image at each point of the height images is calculated (for example, FIG. 1B). As the image analysis software, ImageJ, which is image analysis software published by the National Institutes of Health (NIH), can be used.

As a result, the corrected image of the magnetic layer cross-sectional shape before the scratch operation is acquired.

### (3) Scratch Operation of Magnetic Layer Cross Section

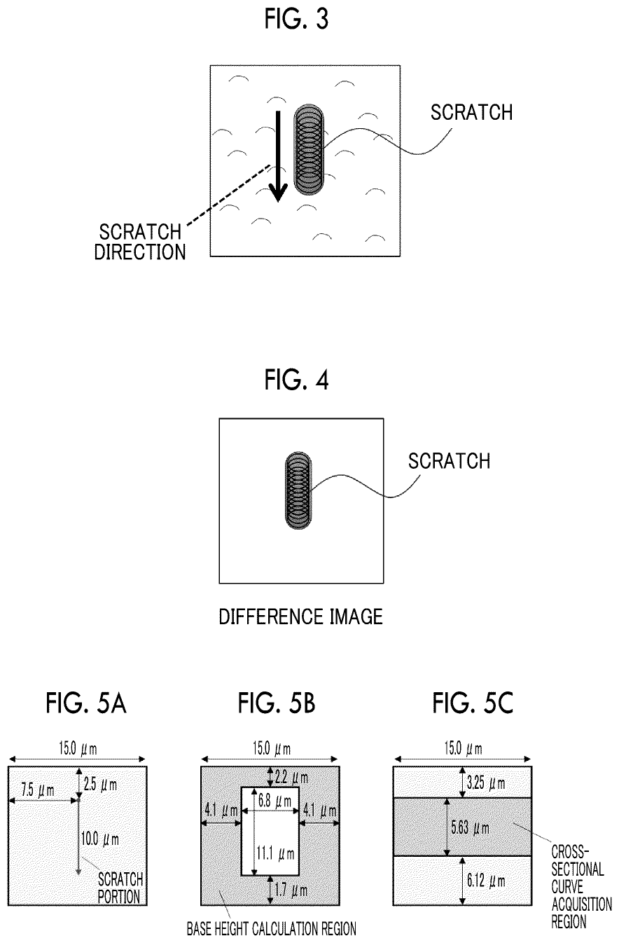

For each of the three cross-section exposed specimens, after the shape measurement of the magnetic layer cross section in (2) above, the magnetic layer cross section is subjected to the scratch operation at room temperature of 20° C. to 25° C. FIG. 2 is a schematic diagram showing a load change during a scratch operation. In FIG. 2, the vertical load is expressed as a negative load. FIG. 3 is a schematic diagram of a magnetic layer cross section on which a scratch is formed by the scratch operation.

A position of 2.5 μm downward from a point in the vicinity of a center in a left-right direction and at an uppermost portion in an up-down direction of a region (15.0 μm×15.0 μm) in which the cross-sectional shape before the scratch operation is measured is defined as a scratch start point, and a position of 10.0 μm downward from the scratch start point is defined as a scratch end point. The indenter is brought into contact with a position of 3.0 μm upward from the scratch start point under a vertical load of 2 μN to apply a load to the magnetic layer cross section and perform the scratch operation. Specifically, a distance of 3.0 μm to the scratch start point is scanned linearly in the downward direction with a vertical load of 2 μN and a scanning speed of 1.5 μm/sec, and the vertical load is increased to 1,000 μN at a rate of 200 μN/sec in a state where the operation at the scratch start point in the horizontal direction is stopped. After the load reaches 1,000 μN, a distance of 10.0 μm from the scratch start point to the scratch end point is scanned linearly downward with a vertical load of 1,000 μN and a scanning speed of 0.67 μm/sec (corresponding to a “constant load scratch” in FIG. 2). After the indenter reaches the scratch end point, the vertical load is decreased to 2 μN at a rate of 200 μN/sec in a state where the operation in the horizontal direction is stopped, and a distance of 3.0 μm downward from the scratch end point is scanned linearly in the downward direction with a vertical load of 2 μN and a scanning speed of 1.5 μm/sec.

By the above-described scratch operation, for example, as shown in FIG. 3, a scratch is formed on the magnetic layer cross section.

(4) Shape Measurement of Magnetic Layer Cross Section after Scratch Operation

For each of the three cross-section exposed specimens, after the scratch operation in (3) above, the shape measurement of the magnetic layer cross section after the scratch operation is performed on the same region as the region in which the shape measurement of the magnetic layer cross section before the scratch operation is performed, under the same conditions. In this case as well, both a height image in a case of scanning the surface in the right direction (right-scan image) and a height image in a case of scanning the surface in the left direction (left-scan image) are acquired, and an image (corrected image) in which the smaller height value is employed by comparing the height values of the right-scan image and the left-scan image at each point of the height images is calculated.

The corrected images acquired before and after the scratch operation are compared, the amount of deviation of the relative position is manually corrected in a case where the deviation of the relative position due to the drift of the specimen is less than 10 pixels (px), and an image (hereinafter, referred to as a “difference image”) with an amount obtained by subtracting the corrected image before the scratch operation from the corrected image after the scratch operation (hereinafter, referred to as a “height change amount”) is calculated. FIG. 4 is a schematic diagram of a difference image. In a case where the deviation of relative position caused by the drift of the specimen is 10 px or more, the measurement result of the region is excluded from the measurement result for calculating the scratch cross-sectional area of the magnetic layer of the electromagnetic wave shielding material to be measured in (5) described later.

FIGS. 5A to 5C are schematic diagrams for describing test conditions. FIG. 5A is a schematic diagram showing a scratch portion in the scratch operation. FIG. 5B is a schematic diagram showing a “base height calculation region” described below. FIG. 5C is a schematic diagram showing a “cross-sectional curve acquisition region” described below.

A region within 2.2 μm from the upper side (side on the scratch start point side in the scratch direction), within 1.7 μm from the lower side, within 4.1 μm from the left side, and within 4.1 μm from the right side of the region where the cross-sectional shape is measured is defined as a “base height calculation region” (see FIG. 5B). The arithmetic average of the height change amounts in the base height calculation region of the difference image is calculated as a “base height”, and an image obtained by subtracting the base height value from the entire difference image (hereinafter, referred to as a “difference image after base height correction”) is calculated.

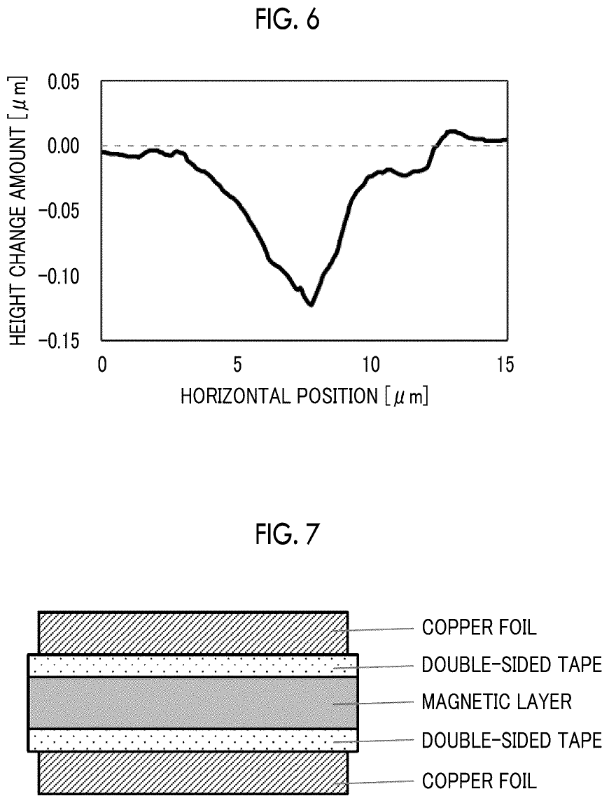

A region from a position of 3.25 μm to a position of 8.88 μm from the upper side of the difference image after base height correction is defined as a “cross-sectional curve acquisition region” (see FIG. 5C). The cross-sectional curve of the cross-sectional curve acquisition region of the difference image after base height correction is acquired by calculating the arithmetic average of the height change amounts in the up-down direction (width of 5.63 μm) at each position in the left-right direction. FIG. 6 is an example of a cross-sectional curve. A sum of values obtained by multiplying a distance in the left-right direction between adjacent data points by an absolute value of the height change amount for the cross-sectional curve is calculated as a “scratch cross-sectional area”.

### (5) Calculation of Scratch Cross-Sectional Area of Magnetic Layer of Electromagnetic Wave Shielding Material to be Measured

The above-described measurement is performed in six measurement regions for each of the three cross-section exposed specimens, and the measurement result of each measurement region is acquired. The distance between different measurement regions is set to be 150 μm or greater. Meanwhile, in a case where the measurement result in the region in which the deviation of relative position caused by the drift of the specimen is 10 px or more in a case of calculating the difference image as described above is excluded, the measurement results of a total of six measurement regions other than the region are acquired to calculate the scratch cross-sectional area. In this way, a total of 18 calculated values of the scratch cross-sectional area are obtained for the three cross-section exposed specimens, and an arithmetic average thereof is taken as the scratch cross-sectional area of the magnetic layer of the electromagnetic wave shielding material to be measured.

From the viewpoint of suppressing the decrease in electromagnetic wave shielding performance of the electromagnetic wave shielding material after being subjected to vibration, the scratch cross-sectional area of the magnetic layer of the electromagnetic wave shielding material is 0.08 μm² or more and 1.25 μm² or less.

From the above-described viewpoint, the scratch cross-sectional area of the magnetic layer of the electromagnetic wave shielding material is preferably 0.09 μm² or more, more preferably 0.10 μm² or more, and still more preferably 0.15 μm² or more and 0.20 μm² or more in this order.

In addition, from the above-described viewpoint, the scratch cross-sectional area of the magnetic layer of the electromagnetic wave shielding material is preferably 1.20 μm² or less, and more preferably 1.15 μm² or less, 1.10 μm² or less, 1.05 μm² or less, 1.00 μm² or less, 0.90 μm² or less, 0.85 μm² or less, 0.80 μm² or less, 0.75 μm² or less, 0.70 μm² or less, 0.65 μm² or less, 0.60 μm² or less, 0.55 μm² or less, 0.50 μm² or less, and 0.45 μm² or less in this order.

The scratch cross-sectional area of the magnetic layer can be controlled, for example, by a method of preparing a composition for forming a magnetic layer. This point will be described below in detail.

Hereinafter, the electromagnetic wave shielding material will be described in more detail.

### <Magnetic Layer>

The magnetic layer is a layer containing magnetic particles. As the magnetic particle, one kind selected from the group consisting of magnetic particles generally called soft magnetic particles, such as metal particles and ferrite particles, can be used, or two or more kinds therefrom can be used in combination. Since the metal particles generally have a saturation magnetic flux density of about 2 to 3 times as compared with ferrite particles, the metal particles can maintain specific magnetic permeability and exhibit shielding performance even under a strong magnetic field without magnetic saturation. Therefore, the magnetic particles to be contained in the magnetic layer are preferably metal particles. In the present invention and the present specification, a layer containing metal particles as the magnetic particles shall correspond to the “magnetic layer”.

### (Metal Particle)

In the present invention and the present specification, the “metal particle” includes a pure metal particle consisting of a single metal element, a particle of an alloy of one or more metal elements, one or two or more other metal elements, and/or a non-metal element. The metal particle may be or may not be crystalline. That is, the metal particle may be a crystalline particle or may be an amorphous particle. Examples of the element of the metal or non-metal contained in the metal particles include Ni, Fe, Co, Mo, Cr, Al, Si, B, and P. The metal particle may or may not contain a component other than the constitutional elements of the metal (including the alloy). The metal particle may contain, in addition to the constitutional element of the metal (including the alloy), elements contained in an additive that can be optionally added and/or elements contained in impurities that can be unintentionally mixed in a manufacturing process of the metal particle at any content rate. In the metal particle, the content of the constitutional element of the metal (including the alloy) is preferably 90.0% by mass or more and more preferably 95.0% by mass or more, and it may be 100% by mass or may be less than 100% by mass, 99.9% by mass or less, or 99.0% by mass or less.

Examples of the metal particles include particles of Sendust (a Fe—Si—Al alloy), permalloy (a Fe—Ni alloy), molybdenum permalloy (a Fe—Ni—Mo alloy), a Fe—Si alloy, a Fe—Cr alloy, a Fe-containing alloy generally called the iron-based amorphous alloy, a Co-containing alloy generally called the cobalt-based amorphous alloy, an alloy generally called the nanocrystal alloy, iron, Permendur (a Fe—Co alloy). Among them, Sendust is preferable since it exhibits a high saturation magnetic flux density and a high specific magnetic permeability.

In one form, a magnetic layer that exhibits a high magnetic permeability (specifically, a real part of a complex specific magnetic permeability) is preferable. In a case where a complex specific magnetic permeability is measured by a magnetic permeability measuring apparatus, a real part μ′ and an imaginary part μ″ are generally displayed. In the present invention and the present specification, a real part of a complex specific magnetic permeability shall refer to such a real part μ′. Hereinafter, a real part of a complex specific magnetic permeability at a frequency of 100 kHz is also simply referred to as “magnetic permeability”. The magnetic permeability can be measured by a commercially available magnetic permeability measuring apparatus or a magnetic permeability measuring apparatus having a known configuration. From the viewpoint that still more excellent electromagnetic wave shielding performance can be exhibited, it is preferable that the magnetic layer included in the electromagnetic wave shielding material is a magnetic layer having a magnetic permeability (the real part of the complex specific magnetic permeability at a frequency of 100 kHz) of 30 or more. The magnetic permeability thereof is more preferably 40 or more, still more preferably 50 or more, still more preferably 60 or more, still more preferably 70 or more, even more preferably 80 or more, even still more preferably 90 or more, and even further still more preferably 100 or more. In addition, the magnetic permeability can be, for example, 200 or less, 190 or less, 180 or less, 170 or less, or 160 or less, and it can exceed the values exemplified here.

From the viewpoint of forming a magnetic layer that exhibits a high magnetic permeability, the magnetic particle is preferably a particle having a flat shape (flat-shaped particle). In a case of arranging the long side direction of the flat-shaped particles to be closer to a state parallel to the in-plane direction of the magnetic layer, the magnetic layer can exhibit a higher magnetic permeability since the diamagnetic field can be reduced by aligning the long side direction of the particle with the vibration direction of the electromagnetic wave incident orthogonal to the electromagnetic wave shielding material. In the present invention and the present specification, the “flat-shaped particle” refers to a particle having an aspect ratio of 0.20 or less. The aspect ratio of the flat-shaped particles is preferably 0.15 or less, and more preferably 0.10 or less. The aspect ratio of the flat-shaped particles can be, for example, 0.01 or more, 0.02 or more, or 0.03 or more. It is possible to make the shape of the particle flat-shaped, for example, by carrying out the flattening process according to a known method. For the flattening process, for example, the description of JP2018-131640A can be referenced, specifically, the description of paragraphs 0016 and 0017 and the description of Examples of the same publication can be referenced. Examples of the magnetic layer that exhibits a high magnetic permeability include a magnetic layer containing flat-shaped particles of Sendust.

As described above, from the viewpoint of forming a layer that exhibits a high magnetic permeability as the magnetic layer, it is preferable to arrange the long side direction of the flat-shaped particles to be closer to a state parallel to the in-plane direction of the magnetic layer. From this point, the alignment degree which is a sum of an absolute value of the average value of alignment angles of the flat-shaped particles with respect to the surface of the magnetic layer and a variance of the alignment angles is preferably 30° or lower, more preferably 25° or lower, still more preferably 20° or lower, and even still more preferably 15° or lower. The alignment degree can be, for example, 3° or higher, 5° or higher, or 10° or higher, and it can be lower than the values exemplified here. A method of controlling the alignment degree will be described later.

In the present invention and the present specification, the aspect ratio of the magnetic particle and the alignment degree are determined according to the following methods.

A cross section of a magnetic layer is exposed according to a known method. In a randomly selected region of this cross section, a cross-sectional image is acquired as a scanning electron microscope (SEM) image. The imaging conditions are set to be an acceleration voltage of 2 kV and a magnification of 1,000 times, and an SEM image is obtained as the backscattered electron image.

Reading is carried out in grayscale with the cv2.imread( ) function of Image processing library OpenCV 4 (manufactured by Intel Corporation) by setting the second argument to 0, and a binarized image is obtained with the cv2.threshold( ) function, using an intermediate brightness between the high-brightness portion and the low-brightness portion as a boundary. A white portion (high-brightness portion) in the binarized image is defined as a magnetic particle.

Regarding the obtained binarized image, a rotational circumscribed rectangle corresponding to a portion of each magnetic particle is determined according to the cv2.minAreaRect( ) function, and the long side length, the short side length, and the rotation angle are determined as the return values of the cv2.minAreaRect( ) function. In a case of determining the total number of magnetic particles included in the binarized image, it shall be assumed that particles in which only a part of the particle is included in the binarized image are also included. Regarding the particles in which only a part of the particle is included in the binarized image, the long side length, the short side length, and the rotation angle of the portion included in the binarized image are determined. The ratio of the short side length to the long side length (short side length/long side length) determined in this way shall be denoted as the aspect ratio of each magnetic particle. In the present invention and the present specification, in a case where the number of magnetic particles which have an aspect ratio of 0.20 or less and is defined as flat-shaped particles is 10% or more on a number basis with respect to the total number of magnetic particles included in the binarized image, it shall be determined that the magnetic layer is a “magnetic layer including flat-shaped particles as the magnetic particles”. In addition, from the rotation angle determined as above, an “alignment angle” is determined as a rotation angle with respect to a horizontal plane (the surface of the magnetic layer).

Particles having an aspect ratio of 0.20 or less, which are determined in the binarized image, are defined as flat-shaped particles. Regarding the alignment angles of all the flat-shaped particles included in the binarized image, the sum of the absolute value of the average value (arithmetic average) and the variance is determined. The sum determined in this way is referred to as the “alignment degree”. It is noted that the coordinates of the circumscribed rectangle are calculated using the cv2.boxPoints( ) function, and an image in which the rotational circumscribed rectangle is superposed on the original image is created according to the cv2.drawContours( ) function, where a rotational circumscribed rectangle that is erroneously detected clearly is excluded from the calculation of the aspect ratio and the alignment degree. In addition, an average value (arithmetic average) of the aspect ratios of the particles defined as the flat-shaped particles shall be denoted as the aspect ratio of the flat-shaped particles to be contained in a magnetic layer to be measured. Such an aspect ratio is 0.20 or less, preferably 0.15 or less, and more preferably 0.10 or less. In addition, the aspect ratio can be, for example, 0.01 or more, 0.02 or more, or 0.03 or more.

The content of the magnetic particles in the magnetic layer can be, for example, 50% by mass or more, 60% by mass or more, 70% by mass or more, and 80% by mass or more with respect to the total mass of the magnetic layer, and it can be, for example, 100% by mass or less, 98% by mass or less, or 95% by mass or less.

In one form, the magnetic layer can be a layer having insulating properties. In the present invention and the present specification, the “insulating properties” associated with the magnetic layer means that the electrical conductivity is smaller than 1 siemens(S)/m. The electrical conductivity of a certain layer is calculated according to the following expression from the surface electrical resistivity of the layer and the thickness of the layer. The electrical conductivity can be measured by a known method.

$$Electrical conductivity [ S / m ] = 1 / ( surface electrical resisitivity [ Ω ] \times thickness [ m ] )$$

The inventors of the present invention presume that it is preferable that the magnetic layer is a layer having insulating properties in order for the electromagnetic wave shielding material to exhibit a higher electromagnetic wave shielding performance. From this point, the electrical conductivity of the magnetic layer is preferably smaller than 1 S/m, more preferably 0.5 S/m or less, still more preferably 0.1 S/m or less, and even still more preferably 0.05 S/m or less. The electrical conductivity of the magnetic layer can be, for example, 1.0×10⁻¹² S/m or more or 1.0×10⁻¹⁰ S/m or more.

### (Resin)

The magnetic layer can contain magnetic particles and a resin. In the magnetic layer containing the magnetic particles and the resin, the content of the resin can be, for example, 1 part by mass or more, 3 parts by mass or more, or 5 parts by mass or more per 100 parts by mass of the magnetic particles, and it can be 20 parts by mass or less or 15 parts by mass or less.

The resin can act as a binder in the magnetic layer. Examples of the resin to be contained in the magnetic layer include known thermoplastic resins in the related art, a thermosetting resin, an ultraviolet curable resin, a radiation curable resin, a rubber-based material, and an elastomer. Specific examples thereof include a polyester resin, a polyethylene resin, a polyvinyl chloride resin, a polyvinyl butyral resin, a polyurethane resin, a cellulose resin, an acrylonitrile-butadiene-styrene (ABS) resin, a nitrile-butadiene rubber, a styrene-butadiene rubber, an epoxy resin, a phenol resin, an amide resin, a styrene-based elastomer, an olefin-based elastomer, a vinyl chloride-based elastomer, a polyester-based elastomer, a polyamide-based elastomer, a polyurethane-based elastomer, and an acrylic elastomer.

In addition to the above-described components, the magnetic layer can also contain any amount of one or more known additives such as a curing agent, a dispersing agent, a stabilizer, and a coupling agent.

The electromagnetic wave shielding material can include only one magnetic layer having a scratch cross-sectional area of 0.08 μm² or more and 1.25 μm² or less, or can include two or more magnetic layers. In addition, the electromagnetic wave shielding material can include one or more magnetic layers having a scratch cross-sectional area of 0.08 μm² or more and 1.25 μm² or less, and can include one or more other layers in addition to such a magnetic layer. A metal layer can be mentioned as one form of the other layer.

In a case where the electromagnetic wave shielding material includes only one magnetic layer having a scratch cross-sectional area of 0.08 μm² or more and 1.25 μm² or less, the thickness of this one magnetic layer can be, for example, 5 μm or more, and it is preferably 10 μm or more and more preferably 20 μm or more from the viewpoint of further improving the shielding performance of the electromagnetic wave shielding material. Meanwhile, the thickness of this one magnetic layer can be, for example, 100 μm or less or 90 μm or less, and it is preferably less than 90 μm, more preferably 80 μm or less, and still more preferably 70 μm or less, from the viewpoint of improving forming workability of the electromagnetic wave shielding material.

In a case where the electromagnetic wave shielding material includes two or more magnetic layers having a scratch cross-sectional area of 0.08 μm² or more and 1.25 μm² or less, the thickness of each of the two or more magnetic layers (that is, the thickness per one layer) can be, for example, 5 μm or more, and it is preferably 10 μm or more and more preferably 20 μm or more from the viewpoint of further improving the shielding performance of the electromagnetic wave shielding material. Meanwhile, the thickness of each of the two or more magnetic layers can be, for example, 100 μm or less or 90 μm or less, and it is preferably less than 90 μm and more preferably 80 μm or less. The thicknesses of the two or more magnetic layers can be the same thickness or thicknesses different from each other.

### <Metal Layer>

In one form, the electromagnetic wave shielding material can include a magnetic layer having a scratch cross-sectional area of 0.08 μm² or more and 1.25 μm² or less, provided between two metal layers. It is presumed that it is preferable that the electromagnetic wave shielding material has a multilayer structure in which the magnetic layer is sandwiched between the two metal layers in order to improve the electromagnetic wave shielding performance of the electromagnetic wave shielding material, particularly the shielding performance against the magnetic field wave.

In the present invention and the present specification, the “metal layer” shall refer to a layer containing a metal. The metal layer can be a layer containing one or more kinds of metals as a pure metal consisting of a single metal element, as an alloy of two or more kinds of metal elements, or as an alloy of one or more kinds of metal elements and one or more kinds of non-metal elements.

In a case where the electromagnetic wave shielding material has a multilayer structure in which the magnetic layer is sandwiched between the two metal layers, the electromagnetic wave shielding material can have one or more such multilayer structures, and can have two or more such multilayer structures. That is, the electromagnetic wave shielding material can include at least two metal layers and can also include three or more layers of metal layer, or it includes at least one magnetic layer and can also include two or more magnetic layers. The two or more layers of metal layer included in the electromagnetic wave shielding material have the same composition and thickness in one form and differ in composition and/or thickness in another form. The same applies to a case where the electromagnetic wave shielding material includes two or more magnetic layers, and the same applies to a case where two or more other layers such as a layer containing a resin described later are included in the electromagnetic wave shielding material.

The metal layer included in the electromagnetic wave shielding material can be a layer that contains one or more kinds of metals selected from the group consisting of various pure metals and various alloys. The metal layer can exhibit an attenuation effect in the shielding material. This point is preferable from the viewpoint of improving the shielding performance of the electromagnetic wave shielding material. Since the attenuation effect increases as the propagation constant increases and the propagation constant increases as the electrical conductivity is higher, it is preferable that the metal layer contains a metal element having a high electrical conductivity. From this point, it is preferable that the metal layer contains, as a main component, a pure metal of Ag, Cu, Au, or Al, or an alloy containing any one of these. The pure metal is a metal consisting of a single metal element and may contain a trace amount of impurities. In general, a metal having a purity of 99.0% or more consisting of a single metal element is called a pure metal. The purity is on a mass basis. The alloy is generally prepared by adding one or more kinds of metal elements or non-metal elements to a pure metal to adjust the composition, for example, in order to prevent corrosion or improve the hardness. The main component in the alloy is a component having the highest ratio on a mass basis, and it can be, for example, a component that occupies 80.0% by mass or more (for example, 99.8% by mass or less) in the alloy. From the viewpoint of economic efficiency, the alloy is preferably an alloy of a pure metal of Cu or Al or an alloy containing Cu or Al as a main component, and from the viewpoint of high electrical conductivity, it is more preferably an alloy of a pure metal of Cu or an alloy containing Cu as a main component.

In one form, the purity of the metal in the metal layer, that is, the content of the metal in the metal layer can be 99.0% by mass or more, 99.5% by mass or more, or 99.8% by mass or more with respect to the total mass of the metal layer. Unless otherwise specified, the content of metal in the metal layer shall refer to the content on a mass basis. For example, as the metal layer, a pure metal or an alloy processed into a sheet shape can be used. For example, as the metal layer, a commercially available metal foil or a metal foil produced by a known method can be used. Regarding a pure metal of Cu, sheets (so-called copper foils) having various thicknesses are commercially available. For example, such a copper foil can be used as the metal layer. The copper foil includes, according to manufacturing methods thereof, an electrolytic copper foil obtained by precipitating a copper foil on a cathode by electroplating and a rolled copper foil obtained by applying heat and pressure to an ingot and stretching the ingot thinly. Any copper foil can be used as the metal layer of the electromagnetic wave shielding material. In addition, for example, regarding Al, sheets (so-called aluminum foils) having various thicknesses are commercially available. For example, such an aluminum foil can be used as the metal layer.

From one or more viewpoints of the viewpoint of economic efficiency, the viewpoint of high electrical conductivity, and the viewpoint of reducing the weight of the electromagnetic wave shielding material, one or both (preferably both) of the two metal layers sandwiching the magnetic layer is preferably a metal layer containing the metal selected from the group consisting of Al, Mg, and Cu, and more preferably a layer containing, as a main component, the metal selected from the group consisting of Al, Mg, and Cu. The main component of the metal layer is a component having the highest ratio on a mass basis. In a layer containing, as a main component, a metal selected from the group consisting of Al, Mg, and Cu, Al, Mg, or Cu is a component having the highest ratio on a mass basis in this layer. Such a layer can contain only one kind of metal or two or three kinds of metals among Al, Mg, and Cu. From the one or more viewpoints, one or both (preferably both) of the two metal layers sandwiching the magnetic layer is preferably a metal layer in which the content of the metal selected from the group consisting of Al, Mg, and Cu is 80.0% by mass or more, and still more preferably a metal layer in which the content of the metal selected from the group consisting of Al, Mg, and Cu is 90.0% by mass or more. The metal layer containing at least Al among Al, Mg, and Cu can be a metal layer in which the Al content is 80.0% by mass or more, and it can be a metal layer in which the Al content is 90.0% by mass or more. The metal layer containing at least Mg among Al, Mg, and Cu can be a metal layer in which the Mg content is 80.0% by mass or more, and it can be a metal layer in which the Mg content is 90.0% by mass or more. The metal layer containing at least Cu among Al, Mg, and Cu can be a metal layer in which the Cu content is 80.0% by mass or more, and it can be a metal layer in which the Cu content is 90.0% by mass or more. The content of the metal selected from the group consisting of Al, Mg, and Cu, the Al content, the Mg content, and the Cu content can be each, for example, 100% by mass or less or 99.9% by mass or less. The content of the metal selected from the group consisting of Al, Mg, and Cu, the Al content, the Mg content, and the Cu content are each the content with respect to the total mass of the metal layer.

From the viewpoint of further improving the processability of the metal layer and the shielding performance of the electromagnetic wave shielding material, the thickness of the metal layer in terms of the thickness per one layer is preferably 4 μm or more, more preferably 5 μm or more, and still more preferably 10 μm or more. On the other hand, from the viewpoint of the processability of the metal layer, the thickness of the metal layer in terms of the thickness per one layer is preferably 200 μm or less, more preferably 100 μm or less, and still more preferably 50 μm or less. In the electromagnetic wave shielding material, the thicknesses of the plurality of metal layers can be the same thickness or thicknesses different from each other.

In one form, one or both of the outermost layers can be a metal layer in the electromagnetic wave shielding material. This point can contribute to the fact that the electromagnetic wave shielding material can exhibit high shielding performance against a magnetic field wave in a low frequency region of about 100 kHz to 1 MHz. In addition, the fact that at least one of the outermost layers of the electromagnetic wave shielding material is a metal layer can contribute to suppressing edge peeling in a formed article obtained by forming processing. In one form, one or both of the outermost layers of the electromagnetic wave shielding material can be a metal layer that sandwiches a magnetic layer together with another metal layer.

In one form, in the electromagnetic wave shielding material, the magnetic layer and the metal layer can be disposed as layers that are directly in contact with each other. That is, the magnetic layer and the metal layer can be adjacent to each other without interposing another layer. For example, in the multilayer structure in which the magnetic layer is sandwiched between the two metal layers, one or both of the two metal layers and the magnetic layer can be disposed as layers directly in contact with each other. That is, one or both of the two metal layers and the magnetic layer can be adjacent to each other without interposing another layer.

In another form, the electromagnetic wave shielding material can have one or more layers containing a resin, provided between the magnetic layer and the metal layer. For example, a multilayer structure in which the magnetic layer is sandwiched between the two metal layers can include one or more layers containing a resin, provided between one or both of the two metal layers and the magnetic layer. The “layer containing a resin” is a layer containing one or more kinds of resins.

### <Layer Containing Resin>

### (Pressure-Sensitive Adhesive Layer)

A pressure-sensitive adhesive layer can be mentioned as one form of the layer containing a resin. In the present invention and the present specification, the “pressure-sensitive adhesive layer” refers to a layer having tackiness on a surface at normal temperature. Regarding the tackiness, the “normal temperature” shall be defined as 23° C. In a case where such a layer comes into contact with an adherend, the layer adheres to the adherend due to the adhesive force thereof. In general, the tackiness is the property of exhibiting an adhesive force in a short time after coming into contact with an adherend with a very light force, and in the present invention and the present specification, the above-described “having tackiness” refers to that the result is No. 1 to No. 32 in a tilted ball tack test (measurement environment: a temperature of 23° C. and a relative humidity of 50%) specified in JIS Z 0237:2009. In a case where another layer is laminated on the surface of the pressure-sensitive adhesive layer, the surface of the pressure-sensitive adhesive layer exposed, for example, by peeling off the other layer can be subjected to the above-described test. In a case where another layer is laminated on each of one surface and the other surface of the pressure-sensitive adhesive layer, the layer on the side of either surface may be peeled off.

As the pressure-sensitive adhesive layer, it is possible to use those obtained by applying a composition for forming a pressure-sensitive adhesive layer containing a pressure sensitive adhesive such as an acrylic pressure sensitive adhesive, a rubber-based pressure-sensitive adhesive, a silicone-based pressure-sensitive adhesive, or a urethane-based pressure-sensitive adhesive and processing it into a film shape.

The composition for forming a pressure-sensitive adhesive layer can be applied onto, for example, a support. The coating can be carried out using a known coating device such as a blade coater or a die coater. The coating can be carried out by a so-called roll-to-roll method or a batch method.

Examples of the support onto which the composition for forming a pressure-sensitive adhesive layer is applied include films of various resins such as polyester such as polyethylene terephthalate (PET) and polyethylene naphthalate (PEN), acryls such as polycarbonate (PC) and polymethyl methacrylate (PMMA), cyclic polyolefin, triacetyl cellulose (TAC), polyether sulfide (PES), polyether ketone, and polyimide. As the support, it is possible to use a support in which a surface (a surface to be coated) onto which the composition for forming a pressure-sensitive adhesive layer is applied is subjected to a peeling treatment according to a known method. One form of the peeling treatment includes forming a release layer. In addition, a commercially available peeling-treated resin film can also be used as the support. In a case of using a support in which the surface to be coated is subjected to the peeling treatment, it is possible to easily separate the pressure-sensitive adhesive layer and the support after the film formation.

By applying a composition for forming a pressure-sensitive adhesive layer, in which a pressure sensitive adhesive is dissolved and/or dispersed in a solvent, onto the surface to be coated and carrying out drying, a pressure-sensitive adhesive layer can be formed. Alternatively, a pressure sensitive adhesive tape including a pressure-sensitive adhesive layer can also be used. As the pressure sensitive adhesive tape, for example, it is possible to use a double-sided tape. The double-sided tape has pressure-sensitive adhesive layers on both sides of the support. In addition, as the pressure sensitive adhesive tape, it is possible to use a pressure sensitive adhesive tape having a pressure-sensitive adhesive layer on one surface of a support. Examples of the support include films of various resins such as polyester such as polyethylene terephthalate (PET) and polyethylene naphthalate (PEN), acryls such as polycarbonate (PC) and polymethyl methacrylate (PMMA), cyclic polyolefin, triacetyl cellulose (TAC), polyether sulfide (PES), polyether ketone, and polyimide, a non-woven fabric, and paper. As the pressure sensitive adhesive tape having a pressure-sensitive adhesive layer on one surface or both surfaces of a support, it is possible to use a commercially available product, or it is possible to use a pressure sensitive adhesive tape produced by a known method.

The thickness of the pressure-sensitive adhesive layer is not particularly limited, and the thickness per layer can be, for example, 1 μm or more and 30 μm or less.

### (Adhesive Layer)

An adhesive layer can also be mentioned as one form of the layer containing a resin. In the present invention and the present specification, the “adhesive layer” is a layer in which a liquid or gel-like adhesive is solidified after coming into contact with an adherend and undergoing a state change such as drying or curing, at that time, adhesiveness to the adherend is exhibited by an anchoring effect, a physical interaction, or formation of a chemical bond to the adherend. In one form, the adhesive layer can be a layer having no tackiness on the surface at normal temperature.

The adhesive contains a resin that is solidified after being dried or cured. Examples of such a resin include a vinyl acetate resin, an ethylene vinyl acetate resin, an epoxy resin, a cyanoacrylate resin, an acrylic resin, a polyurethane resin, a chloroprene rubber, and a styrene butadiene rubber. These resins may be in the form of a liquid or a gel in the resin itself. Alternatively, the solid resin may be dissolved in a solvent to be in a liquid or gel form. Examples of the solvent contained in the adhesive include water, ketone-based solvents such as acetone, methyl ethyl ketone, and cyclohexanone, acetic acid ester-based solvents such as ethyl acetate, butyl acetate, cellosolve acetate, propylene glycol monomethyl ether acetate, and carbitol acetate, carbitols such as cellosolve and butyl carbitol, aromatic hydrocarbon-based solvents such as toluene and xylene, and amide-based solvents such as dimethylformamide, dimethylacetamide, and N-methylpyrrolidone, alcohol-based solvents such as ethanol, methanol, and propanol, and halogen-based solvents such as dichloromethane, trichloroethylene, and dichlorofluoroethane.

The thickness of the adhesive layer is not particularly limited, and the thickness per layer can be, for example, 1 μm or more and 30 μm or less.

### (Resin Layer)

A resin layer can also be mentioned as one form of the layer containing a resin. In the present invention and the present specification, the “resin layer” is a resin film obtained by forming a thermoplastic resin such as a synthetic resin into a film shape, and the resin film has a film-like structure by itself and does not have tackiness at normal temperature.

Examples of the thermoplastic resin contained in the resin film include various resins such as a polyethylene (PE) resin, a polypropylene (PP) resin, a polyvinyl chloride (PVC) resin, a polystyrene (PS) resin, a vinyl acetate resin, a polyurethane resin, a polyvinyl alcohol resin, an ethylene vinyl acetate resin, styrene butadiene rubber, acrylonitrile butadiene rubber, silicone rubber, an olefin-based (PP), a styrene-based elastomer, an acrylonitrile-butadiene-styrene (ABS) resin, polyethylene terephthalate (PET), a polyester resin such as polyethylene naphthalate (PEN), a polycarbonate (PC) resin, an acrylic resin such as polymethyl methacrylate (PMMA), cyclic polyolefin, and triacetyl cellulose (TAC).

The resin layer can be bonded to a metal layer or a magnetic layer by interposing a pressure-sensitive adhesive layer or an adhesive layer. In addition, since the resin layer is a layer containing a thermoplastic resin, the resin layer has the property of being softened by heating and flows and follows minute protrusions and recessions on the surface of the adherend by being pressed against the adherend in a state of being heated, thereby capable of exhibiting an adhesive force due to the anchoring effect, and then it is cooled, whereby the adhered state can be maintained. Therefore, in one form, the resin layer and the other layer can be bonded to each other without interposing the pressure-sensitive adhesive layer or the adhesive layer.

The thickness of the resin layer in terms of the thickness per one resin layer is preferably 10 μm or greater and more preferably 12 μm or greater. The thickness of the resin layer in terms of the thickness per one resin layer is preferably 250 μm or less, more preferably 230 μm or less, still more preferably 210 μm or less, and even still more preferably 190 μm or less. In one form, the electromagnetic wave shielding material can include, in a multilayer structure in which the magnetic layer is sandwiched between the two metal layers, one or more resin layers having a thickness in the above range between one or both of the two metal layers and the magnetic layer. For example, the multilayer structure can include one resin layer having a thickness in the above range between one metal layer of the two metal layers and the magnetic layer and/or between the other metal layer and the magnetic layer.

### Specific Example of Layer Configuration

The total number of the magnetic layers included in the electromagnetic wave shielding material is such that one or more layers are included, one layer can be included, two or more layers can be included, and for example, four or less layers can be included. In a case where the electromagnetic wave shielding material includes two or more magnetic layers, it is preferable that a scratch cross-sectional area of some or all of the two or more magnetic layers is in the range described above, and the scratch cross-sectional area of all the magnetic layers is in the range described above.

Meanwhile, the total number of the metal layers included in the electromagnetic wave shielding material is such that zero layer or one or more layers are included, two or more layers can be included, and for example, two to five layers can be included.

In one form, in a multilayer structure in which the magnetic layer is sandwiched between two metal layers, the magnetic layer can be in direct contact with both metal layers. In this case, specific examples of the layer configuration of the electromagnetic wave shielding material include the following examples.
Example A1: “Metal layer/magnetic layer/metal layer”
Example A2: “Metal layer/magnetic layer/metal layer/magnetic layer/metal layer”
Example A3: “Metal layer/magnetic layer/metal layer/magnetic layer/metal layer/magnetic layer/metal layer”

In an electromagnetic wave shielding material having two or more multilayer structures that include the magnetic layer between two metal layers, for example, as in Example A2 and Example A3, a metal layer that sandwiches a magnetic layer in a certain multilayer structure can also be a metal layer that sandwiches a magnetic layer in another multilayer structure. In the electromagnetic wave shielding material, the total number of multilayer structures including the magnetic layer between two metal layers can be, for example, 1 to 4. The total number of the multilayer structures is one in Example A1, two in Example A2, and three in Example A3. It is preferable that the total number of the multilayer structures is two or more (for example, two, three, or four) from the viewpoint of further improving the shielding performance of the electromagnetic wave shielding material. In the above, the symbol “/” means that the layer described on the left side of this symbol and the layer described on the right side of this symbol are in direct contact with each other without another layer being interposed therebetween. This point is also the same in the following description unless otherwise noted.

In another form, a multilayer structure that includes the magnetic layer between the two metal layers of the electromagnetic wave shielding material can include one or more layers containing a resin between one or both of the two metal layers and the magnetic layer. In the above-described multilayer structure, one of the two metal layers may be adjacent to the magnetic layer without interposing another layer, and one or more layers containing a resin may be included between the other metal layer and the magnetic layer. In addition, the multilayer structure may include one or more layers containing a resin, provided between each of the two metal layers and the magnetic layer.

The multilayer structure can include a pressure-sensitive adhesive layer and/or an adhesive layer between the resin layer and the metal layer. In one form, in the multilayer structure, the pressure-sensitive adhesive layer and/or the adhesive layer may be included between the resin layer and the magnetic layer. In another form, in the multilayer structure, the resin layer and the magnetic layer can be in direct contact with each other. That is, the resin layer and the magnetic layer can be adjacent to each other without interposing another layer.

The electromagnetic wave shielding material can include, for example, a total of 1 to 12 layers containing a resin. The total number of layers of resin layers (preferably the resin layers having the thickness described above) included in the electromagnetic wave shielding material can be, for example, one to four layers. The total number of layers of layers selected from the group consisting of the pressure-sensitive adhesive layer and the adhesive layer, which are included in the electromagnetic wave shielding material, can be, for example, one to four layers or one to eight layers.

Examples of the disposition of the “magnetic layer”, the “metal layer”, the “resin layer”, and the “pressure-sensitive adhesive layer or adhesive layer” in the electromagnetic wave shielding material include the following examples. In the following examples, the “pressure-sensitive adhesive layer” may include a support, and the “pressure-sensitive adhesive layer” may be a pressure sensitive adhesive tape having a pressure-sensitive adhesive layer on one or both surfaces of the support. For example, as in Example B3, metal layers that sandwich a certain magnetic layer can be metal layers that sandwich another magnetic layer. For example, in Example B3, the metal layer 2 is one of the two metal layers that sandwich the magnetic layer 1, and it is also one of the two metal layers that sandwich the magnetic layer 2. In addition, in Example B3, one of the outermost layers of the electromagnetic wave shielding material is the metal layer 1 that sandwiches the magnetic layer 1 together with the metal layer 2, and the other of the outermost layers of the electromagnetic wave shielding material is the metal layer 3 that sandwiches the magnetic layer 2 together with the metal layer 2.
Example B1: “Metal layer 1/pressure-sensitive adhesive layer 1 or adhesive layer 1/resin layer 1/magnetic layer 1/resin layer 2/pressure-sensitive adhesive layer 2 or adhesive layer 2/metal layer 2”
Example B2: “Metal layer 1/pressure-sensitive adhesive layer 1 or adhesive layer 1/resin layer 1/magnetic layer 1/metal layer 2/pressure-sensitive adhesive layer 2 or adhesive layer 2/resin layer 2”
Example B3: “Metal layer 1/pressure-sensitive adhesive layer 1 or adhesive layer 1/resin layer 1/magnetic layer 1/resin layer 2/pressure-sensitive adhesive layer 2 or adhesive layer 2/metal layer 2/pressure-sensitive adhesive layer 3 or adhesive layer 3/resin layer 3/magnetic layer 2/resin layer 4/pressure-sensitive adhesive layer 4 or adhesive layer 4/metal layer 3”
Example B4: “Metal layer 1/pressure-sensitive adhesive layer 1 or adhesive layer 1/resin layer 1/magnetic layer 1/metal layer 2/pressure-sensitive adhesive layer 2 or adhesive layer 2/resin layer 2/magnetic layer 2/resin layer 3/pressure-sensitive adhesive layer 3 or adhesive layer 3/metal layer 3”
Example B5: “Metal layer 1/pressure-sensitive adhesive layer 1 or adhesive layer 1/resin layer 1/magnetic layer 1/metal layer 2/pressure-sensitive adhesive layer 2 or adhesive layer 2/resin layer 2/magnetic layer 2/metal layer 3/pressure-sensitive adhesive layer 3 or adhesive layer 3/resin layer 3”
Example B6: “Metal layer 1/pressure-sensitive adhesive layer 1 or adhesive layer 1/resin layer 1/magnetic layer 1/metal layer 2/magnetic layer 2/resin layer 2/pressure-sensitive adhesive layer 2 or adhesive layer 2/metal layer 3”
Example B7: “Metal layer 1/pressure-sensitive adhesive layer 1 or adhesive layer 1/resin layer 1/magnetic layer 1/metal layer 2/magnetic layer 2/metal layer 3/pressure-sensitive adhesive layer 2 or adhesive layer 2/resin layer 2”
Example B8: “Metal layer 1/pressure-sensitive adhesive layer 1 or adhesive layer 1/resin layer 1/magnetic layer 1/resin layer 2/pressure-sensitive adhesive layer 2 or adhesive layer 2/metal layer 2/magnetic layer 2/resin layer 3/pressure-sensitive adhesive layer 3 or adhesive layer 3/metal layer 3”
Example B9: “Resin layer 1/pressure-sensitive adhesive layer 1 or adhesive layer 1/metal layer 1/magnetic layer 1/metal layer 2/pressure-sensitive adhesive layer 2 or adhesive layer 2/resin layer 2”

### <Manufacturing Method for Electromagnetic Wave Shielding Material>

### (Film Forming Method for Magnetic Layer)

The magnetic layer can be produced, for example, by drying a coating layer that is provided by applying a composition for forming a magnetic layer. The composition for forming a magnetic layer can contain the components described above and can further contain one or more kinds of solvents. Examples of the solvent include various organic solvents, for example, ketone-based solvents such as acetone, methyl ethyl ketone, and cyclohexanone, acetic acid ester-based solvents such as ethyl acetate, butyl acetate, cellosolve acetate, propylene glycol monomethyl ether acetate, and carbitol acetate, carbitols such as cellosolve and butyl carbitol, aromatic hydrocarbon-based solvents such as toluene and xylene, and amide-based solvents as such dimethylformamide, dimethylacetamide, and N-methylpyrrolidone. One kind of solvent or two or more kinds of solvents selected in consideration of the solubility of the component that is used in the preparation of the composition for forming a magnetic layer can be mixed at any ratio and used. The solvent content of the composition for forming a magnetic layer is not particularly limited and may be determined in consideration of the coatability of the composition for forming a magnetic layer.

The composition for forming a magnetic layer can be prepared by sequentially mixing various components in any order or simultaneously mixing them. In addition, as necessary, a dispersion treatment can be carried out using a known dispersing machine such as a ball mill, a bead mill, a sand mill, or a roll mill, and/or a stirring treatment can be also carried out using a known stirrer such as a shaking type stirrer. In a case where a composition for forming a magnetic layer with less inclusion of bubbles is used, the value of the scratch cross-sectional area of the formed magnetic layer tends to be smaller. Examples of means for suppressing the inclusion of bubbles in the composition for forming a magnetic layer include suppressing the generation of bubbles in the stirring treatment and/or performing a defoaming treatment of the composition for forming a magnetic layer after the stirring treatment.

The composition for forming a magnetic layer can be applied onto, for example, a support. The coating can be carried out using a known coating device such as a blade coater or a die coater. The coating can be carried out by a so-called roll-to-roll method or a batch method. A coating speed in a case of performing coating is not particularly limited.

Examples of the support onto which the composition for forming a magnetic layer is applied include films of various resins such as polyester such as polyethylene terephthalate (PET) and polyethylene naphthalate (PEN), acryls such as polycarbonate (PC) and polymethyl methacrylate (PMMA), cyclic polyolefin, triacetyl cellulose (TAC), polyether sulfide (PES), polyether ketone, and polyimide. For these resin films, reference can be made to paragraphs 0081 to 0086 of JP2015-187260A. As the support, it is possible to use a support in which a surface (a surface to be coated) onto which the composition for forming a magnetic layer is applied is subjected to a peeling treatment according to a known method. One form of the peeling treatment includes forming a release layer. For the release layer, reference can be made to paragraph 0084 of JP2015-187260A. In addition, a commercially available peeling-treated resin film can also be used as the support. In a case of using a support in which the surface to be coated is subjected to the peeling treatment, it is possible to easily separate the magnetic layer and the support after the film formation.

In one form, it is also possible to directly apply the composition for forming a magnetic layer onto the metal layer using the metal layer as a support. In a case of directly applying the composition for forming a magnetic layer onto the metal layer, it is possible to manufacture a laminated structure of the metal layer and the magnetic layer in one step.

A coating layer formed by applying the composition for forming a magnetic layer can be subjected to a drying treatment according to a known method such as heating or warm air blowing. The drying treatment can be carried out, for example, under conditions in which the solvent contained in the composition for forming a magnetic layer can be volatilized. As an example, the drying treatment can be carried out for 1 minute to 2 hours in a heated atmosphere having an atmospheric temperature of 80° C. to 150° C.

The alignment degree of the flat-shaped particle described above can be controlled by a solvent kind, solvent amount, liquid viscosity, coating thickness, and the like of the composition for forming a magnetic layer. For example, in a case where the boiling point of the solvent is low, convection occurs due to drying, and thus the value of the alignment degree tends to be large. In a case where the solvent amount is small, the value of the alignment degree tends to increase due to physical interference between adjacent flat-shaped particles. On the other hand, in a case where the liquid viscosity is low, the rotation of flat-shaped particles is more likely to occur, and thus the value of the alignment degree tends to be small. The value of the alignment degree tends to be small as the coating thickness decreases. In addition, carrying out a pressurization treatment described later can contribute to reducing the value of the alignment degree. In a case of adjusting the various manufacturing conditions described above, the alignment degree of the flat-shaped particles can be controlled within the range described above.

### (Pressurization Treatment of Magnetic Layer)

A pressurization treatment can also be performed on the magnetic layer after film formation. In a case of subjecting the magnetic layer containing the magnetic particles to a pressurization treatment, it is possible to increase the density of the magnetic particles in the magnetic layer, and it is possible to obtain a higher magnetic permeability. In addition, in the magnetic layer containing the flat-shaped particles, it is possible to reduce the value of the alignment degree by the pressurization treatment, and it is possible to obtain a higher magnetic permeability.

The pressurization treatment can be carried out by applying pressure in the thickness direction of the magnetic layer using a flat plate pressing machine, a roll pressing machine, or the like. In the flat plate pressing machine, an object to be pressurized can be disposed between two flat press plates that are disposed vertically, and the two press plates can be put together by mechanical or hydraulic pressure to apply pressure to the object to be pressurized. In the roll pressing machine, an object to be pressurized is allowed to pass between the rotating pressurization rolls that are disposed vertically, and at that time, mechanical or hydraulic pressure is applied to the pressurization rolls, or the distance between the pressurization rolls is made to be smaller than the thickness of the object to be pressurized, whereby the pressure can be applied.

The pressure during the pressurization treatment can be set freely. For example, in a case of a flat plate pressing machine, it is, for example, 1 to 50 newtons (N)/mm². In a case of a roll pressing machine, it is, for example, 20 to 400 N/mm in terms of the linear pressure.

The pressurization time can be set freely. It takes, for example, 5 seconds to 30 minutes in a case where a flat plate pressing machine is used. In a case where a roll pressing machine is used, the pressurization time can be controlled by the transport speed of the object to be pressurized, where the transport speed is, for example, 10 cm/min to 200 m/min.

The materials of the press plate and the pressurization roll can be randomly selected from metal, ceramics, plastic, and rubber.

In the pressurization treatment, it is also possible to carry out a pressurization treatment by applying a temperature to both of upper and lower press plates of a plate-shape pressing machine or one press plate thereof, or one roll of upper and lower rolls of a roll pressing machine. The magnetic layer can be softened by heating, which makes it possible to obtain a high compression effect in a case where pressure is applied. The temperature at the time of heating can be set freely, and it is, for example, 50° C. or higher and 200° C. or lower. The temperature at the time of heating can be the internal temperature of the press plate or the roll. Such a temperature can be measured with a thermometer installed inside the press plate or the roll.

After the heating and pressurization treatment with the plate-shape pressing machine, the press plates can be spaced apart from each other, for example, in a state where the temperature of the press plates is high, whereby the magnetic layer can be taken out. Alternatively, the press plate can be cooled by a method such as water cooling or air cooling while maintaining the pressure, and then the press plates can be spaced apart to take out the magnetic layer.

In the roll pressing machine, the magnetic layer can be cooled immediately after pressing, by a method such as water cooling or air cooling.

It is also possible to repeat the pressurization treatment two or more times.

In a case where the magnetic layer is formed into a film on a release film, it is possible to carry out a pressurization treatment, for example, in a state where the magnetic layer is laminated on the release film. Alternatively, the magnetic layer can also be peeled off from the release film and can be subjected to a pressurization treatment as a single layer of the magnetic layer.

### (Bonding of Various Layers)

A pressure-sensitive adhesive layer or an adhesive layer can be used for bonding various layers. The pressure-sensitive adhesive layer and the adhesive layer are as described above.

In addition, in the electromagnetic wave shielding material, two layers adjacent to each other can be also adhered to each other, for example, by applying pressure and heat to carry out crimping. A plate-shape pressing machine, a roll pressing machine, or the like can be used for the crimping. For example, in a case where the magnetic layer is disposed as a layer that is in direct contact with the adjacent layer, the magnetic layer is softened in a crimping step, and the contact with the surface of the adjacent layer is promoted, whereby the magnetic layer and the adjacent layer can be bonded to each other without interposing another layer. The pressure at the time of crimping can be set freely. It is, for example, 1 to 50 N/mm² in a case of a plate-shape pressing machine. In a case of a roll pressing machine, it is, for example, 20 to 400 N/mm in terms of the linear pressure. The pressurization time at the time of crimping can be set freely. It takes, for example, 5 seconds to 30 minutes in a case where a plate-shape pressing machine is used. In a case where a roll pressing machine is used, the pressurization time can be controlled by a transport speed of an object to be pressurized, and the transport speed is, for example, 10 cm/min to 200 m/min. The temperature at the time of crimping can be selected freely, and it is, for example, 20° C. or higher and 200° C. or lower. The temperature at the time of crimping can be, for example, the internal temperature of the press plate or the roll.

### <Coating of Edge Surface of Magnetic Layer>

In one form, the electromagnetic wave shielding material can be an electromagnetic wave shielding material having a multilayer structure having the magnetic layer, between two metal layers, in which a part or whole of an edge surface of the magnetic layer is coated with a coating material.

In the multilayer structure, the magnetic layer is located between two metal layers. Accordingly, in a case where one of a pair of surfaces of the magnetic layer is referred to as an upper surface and the other thereof is referred to as a lower surface, a surface of one metal layer of the two metal layers faces the upper surface, and a surface of the other metal layer faces the lower surface. The “edge surface” of such a magnetic layer is a surface that does not face the surface of the metal layer, that is, a side surface. It is noted that the terms “upper surface” and “lower surface” are used as terms for indicating a relative positional relationship between a pair of surfaces of the magnetic layer, and thus the electromagnetic wave shielding material is not limited to being used in a state where the upper surface and the lower surface are disposed parallel to a horizontal plane.

The electromagnetic wave shielding material can have any shape such as a sheet shape (also can be referred to as a film shape) and any size. For example, a sheet-shaped electromagnetic wave shielding material can be bent into any shape and incorporated into an electronic component or an electronic apparatus. In the multilayer structure included in the sheet-shaped electromagnetic wave shielding material, the magnetic layer and the metal layer can also have a sheet shape. The sheet shape can be, for example, a sheet shape having an upper surface, a lower surface, and four edge surfaces, where the surface shapes of the upper surface and the lower surface can be, for example, rectangular. The rectangular upper surface and the rectangular lower surface can have the same size or can have sizes different from each other. It is noted that with regard to the “same size” and the “same” associated with the surface shape described in the present specification, the manufacturing error that can generally occur is allowed. The surface of the metal layer facing the upper surface of the sheet-shaped magnetic layer having an upper surface, a lower surface, and four edge surfaces can have the same size and the same surface shape as the upper surface of the magnetic layer in one form, and in another form, it can be different in size and/or surface shape from the upper surface of the magnetic layer. Regarding the surface of the metal layer facing the lower surface of the magnetic layer as well, the surface of the metal layer facing the lower surface of the sheet-shaped magnetic layer having an upper surface, a lower surface, and four edge surfaces can have the same size and the same surface shape as the lower surface of the magnetic layer in one form, and in another form, it can be different in size and/or surface shape from the lower surface of the magnetic layer. For example, in the multilayer structure, the edge surface of the magnetic layer can be in a state of protruding outward from the edge surfaces of the two metal layers in one form, and in another form, it can be in a state of being retracted inward from the end surfaces of the two metal layers. In addition, in another form, the upper and lower surfaces can have the same size and have the same surface shape in both the two metal layers and the magnetic layer, which are included in the multilayer structure. In any case, in the electromagnetic wave shielding material, a part or whole of an edge surface of the magnetic layer is coated with a coating material.

### (Coating Material)

As a coating material that coats a part or whole of the edge surface of the magnetic layer, various adhesives, liquid or solid sealing agents, resin films, pressure-sensitive adhesive tapes, metal foils with an adhesive layer, and the like can be used. For example, in a multilayer structure produced as described above, in a case where a coating material is bonded, by a known method, to a part or whole of the edge surface of the magnetic layer, which is exposed without being coated by the metal layer, a part or whole of the edge surface of the magnetic layer can be coated with the coating material. On the other hand, the edge surface of the metal layer included in the multilayer structure may not be coated with a coating material, or a part or entire surface of the edge surface may be coated with a coating material.

In one form, the coating material that coats the edge surface of the magnetic layer can be only one kind of coating material. In another form, a coating material that coats a part of the edge surface of the magnetic layer and a coating material that coats the other part thereof can be respectively coating materials having thicknesses and/or compositions different from each other. For example, in one form, all four edge surfaces of a sheet-shaped magnetic layer having an upper surface, a lower surface, and four edge surfaces can be coated with the same coating material. In another form, a coating material that coats one or more of the four edge surfaces and a coating material that coats the other one or more thereof can be respectively coating materials having thicknesses and/or compositions different from each other. A part or entire surface of each edge surface can be coated with a coating material. The thickness of the coating material can be, for example, 10 μm or more or 30 μm or more, and can be, for example, 300 μm or less or 200 μm or less.

In one form, a part or whole of the coating material that coats the edge surface of the magnetic layer can be a coating material having a thermal conductivity higher than a thermal conductivity of the magnetic layer. It is preferable to coat a part or whole of the edge surface of the magnetic layer with a coating material having a thermal conductivity higher than a thermal conductivity of the magnetic layer from the viewpoint of improving the thermal conductivity of the electromagnetic wave shielding material and improving the heat radiation properties. The coating material having a high thermal conductivity can be selected from those containing a material having a high thermal conductivity. Examples of the material having a high thermal conductivity include various metals or ceramics and semiconductors. A simple body or a mixture of these materials having a high thermal conductivity, or a composite thereof with a resin or the like can be used as a coating material having a high thermal conductivity.

A measuring method for the thermal conductivity is classified into a steady state method and a non-steady state method. In the present invention and the present specification, the “thermal conductivity” shall refer to a thermal conductivity measured by a steady state method. Specific examples of the measuring method for the thermal conductivity include a method described for Examples described later.

In the coating material having a thermal conductivity higher than a thermal conductivity of the magnetic layer, the thermal conductivity is more than 1.0, preferably 1.2 or more, and more preferably 1.4 or more, with the thermal conductivity of the magnetic layer as a reference (1.0). In addition, in the coating material having a thermal conductivity higher than a thermal conductivity of the magnetic layer, the thermal conductivity can be, for example, 3.0 or less or 2.5 or less with the thermal conductivity of the magnetic layer as a reference (1.0), or it can exceed the values exemplified here.

For example, the coating material that coats one or more edge surfaces of a sheet-shaped magnetic layer having an upper surface, a lower surface, and four edge surfaces can be a coating material having a thermal conductivity higher than a thermal conductivity of the magnetic layer. More specifically, the coating material that coats one or more edge surfaces can be a coating material having a thermal conductivity higher than a thermal conductivity of the magnetic layer, where the thermal conductivity of the coating material that coats the other one or more edge surfaces is equal to or smaller than the thermal conductivity of the magnetic layer, or all of the edge surfaces coated with a coating material among the four edge surfaces can be coated with a coating material having a thermal conductivity higher than a thermal conductivity of the magnetic layer. Alternatively, all the four edge surfaces can be coated with a coating material having a thermal conductivity higher than a thermal conductivity of the magnetic layer. In one form, only a part of each of the edge surfaces can be coated with a coating material having a thermal conductivity higher than a thermal conductivity of the magnetic layer, and in another form, the entire surface can be coated with a coating material having a thermal conductivity higher than a thermal conductivity of the magnetic layer.

In addition, in one form, a part or whole of the coating material that coats the edge surface of the magnetic layer can be a conductive coating material. In the present invention and the present specification, regarding the coating material, the “conductivity” shall refer to that the resistivity ρ is 1 Ω·m or less, and the “insulating properties” shall refer to that such conductivity is not provided. The resistivity ρ of the conductive coating material is 1 Ω·m or less and can be, for example, 0.1 Ω·m or less, where it is preferably 0.01 Ω·m or less and more preferably 0.001 Ω·m or less. The resistivity ρ of the conductive coating material can be, for example, 0.2 mΩ·m or more or 0.5 mΩ·m or more, or it can be lower than the values exemplified here. The resistivity ρ is a value calculated according to the following expression by measuring a resistance value R (unit: Ω) of a measurement target and using a cross-sectional area S (unit: m²) of the measurement target and a distance L [m] between electrodes. The resistance value R can be measured by using a known measuring device capable of measuring a resistance value, such as a commercially available digital multimeter. Specific examples of the measuring method for the resistivity ρ include a method described for Examples described later.

$$Resistivity ρ ( unit : Ω \cdot m ) = RS / L$$

As the conductive coating material, various metal foils, metal plates, conductive tapes, conductive adhesives, and the like can be used. It is preferable to use a conductive coating material from the following viewpoints. In a shielding material having a multilayer structure in which a magnetic layer containing magnetic particles is sandwiched between two metal layers, in a case where one outermost layer and the other outermost layer are both metal layers, the one metal layer can be conductively connected to the metal case in a case where the shielding material is attached to a metal case of an electronic circuit. However, since the other metal layer is generally disposed with the magnetic layer being interposed, which tends to have a large electric resistance, it is assumed that the conductive connection to the metal case cannot be obtained. In this case, the other metal layer described above is a so-called floating conductor, which can cause cavity resonance between the other metal layer and a signal wire of an electronic circuit and can cause strong noise. In addition, the other metal layer described above may be charged by the operation of the electronic circuit, which may cause a voltage increase or static electricity. Therefore, it is preferable that there is a conductive connection between the metal layers of the shielding material. Regarding this point, in order to ensure a conductive connection between metal layers, it is preferable that the coating material that coats the edge surface of the magnetic layer has conductivity, and it is more preferable that the conductive coating material is in contact with both one metal layer and the other metal layer. In the two metal layers, in a case where the resistance value between metal layers is 100Ω or less, it can be said that there is a conductive connection between the metal layers. In a case where there is a conductive connection between metal layers, the resistance value between metal layers can be, for example, 10Ω or less, where it is preferably 1Ω or less and more preferably 0.5Ω or less. The resistance value between metal layers can be, for example, 20 mΩ or more or 50 mΩ or more, or it can be lower than the values exemplified here. The resistance value between metal layers can be measured by using a known measuring device capable of measuring a resistance value, such as a commercially available digital multimeter. Specific examples of the measuring method for the resistance value between metal layers include a method described for Examples described later.

For example, the coating material that coats one or more edge surfaces of a sheet-shaped magnetic layer having an upper surface, a lower surface, and four edge surfaces can be a conductive coating material. More specifically, the coating material that coats one or more edge surfaces can be a conductive coating material, where the coating material that coats the other one or more edge surfaces can be an insulating coating material, or all of the edge surfaces coated with a coating material among the four edge surfaces can be coated with a conductive coating material. Alternatively, all the four edge surfaces can be coated with a conductive coating material. In one form, only a part of each of the edge surfaces can be coated with a conductive coating material, and in another form, the entire surface can be coated with a conductive coating material. It is preferable that the entire surface of each of the four edge surfaces is coated with a conductive coating material having a thermal conductivity higher than a thermal conductivity of the magnetic layer.

The electromagnetic wave shielding material can be incorporated into, in any shape, an electronic component or an electronic apparatus. The electromagnetic wave shielding material can have a sheet shape, where the size thereof is not particularly limited. In the present invention and the present specification, the “sheet” has the same meaning as the “film”. In addition, the electromagnetic wave shielding material can be a three-dimensionally formed article obtained by three-dimensionally forming a sheet-shaped electromagnetic wave shielding material, or it can also be a sheet-shaped electromagnetic wave shielding material for three-dimensional forming. As a three-dimensional forming method, it is possible to use various forming methods such as mold press forming, vacuum forming, and air pressure forming. Regarding the forming method, for example, the forming that is carried out without heating a forming target and/or a mold or carried out by heating a forming target and/or a mold without raising the temperature too much is generally called cold forming. Examples of the forming method of the cold forming include draw forming and bulge forming. The draw forming is a forming method in which a sheet-shaped forming target is pressed using a pair of molds of a female die and a male die, thereby being formed into bottomed containers having various shapes such as a cylinder, a square cylinder, and a conical shape. In contrast, a method of forming a formed article having a shape in which a curved surface protrudes from a flat surface, from a sheet-shaped forming target is bulge forming. The bulge forming can be carried out by pressing with only a male die without a female die. The draw forming is roughly classified into deep draw forming and shallow draw forming. A formed article having a shallow depth is formed by the shallow draw forming, and a formed article having a deep depth (for example, having a depth that is deeper than a diameter of a cylinder or a cone, or a length of one side of a pyramid) is formed by the deep draw forming. Known techniques can be applied to the three-dimensional forming method.

### [Electronic Component]

One aspect of the present invention relates to an electronic component including the electromagnetic wave shielding material. Examples of the electronic component include an electronic component included in an electronic apparatus such as a mobile phone, a mobile information terminal, and a medical device, and various electronic components such as a semiconductor element, a capacitor, a coil, and a cable. The electromagnetic wave shielding material is three-dimensionally formed into any shape, for example, according to the shape of the electronic component, thereby capable of being disposed in the inside of the electronic component, or it is three-dimensionally formed into a shape of a cover material, thereby capable of being disposed as a cover material that covers the outside of the electronic component. Alternatively, it can be three-dimensionally formed into a tubular shape, thereby being disposed as a cover material that covers the outside of the cable.

### [Electronic Apparatus]

One aspect of the present invention relates to an electronic apparatus including the electromagnetic wave shielding material. Examples of the electronic apparatus include electronic apparatuses such as a mobile phone, a mobile information terminal, and a medical device, electronic apparatuses including various electronic components such as a semiconductor element, a capacitor, a coil, and a cable, and electronic apparatuses in which electronic components are mounted on a circuit board. Such an electronic apparatus can include the electromagnetic wave shielding material as a constitutional member of an electronic component included in the device. In addition, as a constitutional member of the electronic apparatus, the electromagnetic wave shielding material can be disposed in the inside of the electronic apparatus or can be disposed as a cover material that covers the outside of the electronic apparatus. Alternatively, it can be three-dimensionally formed into a tubular shape, thereby being disposed as a cover material that covers the outside of the cable.

Examples of the usage form of the electromagnetic wave shielding material include a usage form in which a semiconductor package on a printed board is coated with an electromagnetic wave shielding material. For example, “Electromagnetic wave shielding technology in a semiconductor package” (Toshiba Review Vol. 67, No. 2 (2012) P. 8) discloses a method of obtaining a high shielding effect by electrically connecting a side via of an end part of a package substrate and an inner surface of an electromagnetic wave shielding material in a case where a semiconductor package is coated with an electromagnetic wave shielding material, thereby carrying out ground wiring. In order to carry out such wiring, it is desirable that the outermost layer of the electromagnetic wave shielding material on the electronic component side is a metal layer. In a case where one or both of the outermost layers of the electromagnetic wave shielding material is a metal layer in the electromagnetic wave shielding material, the electromagnetic wave shielding material can be suitably used in a case of carrying out the wiring as described above.

### EXAMPLES

Hereinafter, the present invention will be described in more detail with reference to Examples. However, the present invention is not limited to the embodiments shown in Examples. Unless otherwise specified, the following various steps were performed at room temperature of 20° C. to 25° C.

### Example 1

### <Preparation of Coating Liquid (Composition for Forming Magnetic Layer)>

To a plastic bottle, the following substances were added and the mixture was subjected to shaking type stirring with a shaking type stirrer for 1 hour to prepare a coating liquid;
100 g of Fe—Si—Al flat-shaped magnetic particles (Sendust MFS-SUH manufactured by MKT),
12 g of a polystyrene polybutadiene block copolymer (manufactured by Sigma-Aldrich Japan), and
205 g of cyclohexanone.

Thereafter, the prepared coating liquid was subjected to a defoaming treatment by ultrasonic degassing (output: 200 W, frequency: 28 kHz) for the time (in Table 1, “coating liquid defoaming time”) shown in Table 1.

### <Production of Magnetic Layer>

### (Formation of Film of Magnetic Layer)

A coating liquid after defoaming treatment was applied onto a peeling surface of a peeling-treated PET film (PET75TR manufactured by NIPPA Co., Ltd.) with a blade coater having a coating gap of 300 μm and dried for 30 minutes in a drying device having an internal atmospheric temperature of 80° C. to form a film of a sheet-shaped magnetic layer.

### (Pressurization Treatment of Magnetic Layer)

Upper and lower press plates of a plate-shape pressing machine (a large-scale hot press TA-200-1 W manufactured by YAMAMOTO ENG. WORKS Co., LTD.) were heated to 140° C. (the internal temperature of the press plate), and the magnetic layer on the release film was installed in the center of the press plate together with the release film and held for 10 minutes in a state where a pressure of 4.66 N/mm² was applied. The upper and lower press plates were cooled to 50° C. (the internal temperature of the press plates) while maintaining the pressure, and then the magnetic layer was taken out together with the release film.

### <Formation of Multilayer Structure>

A sample piece for each of the following measurement of magnetic permeability, the following measurement of electrical conductivity, and the following measurement of thermal conductivity was cut off from a part of the magnetic layer after the release film was peeled off. A double-sided tape (NeoFix 5 S2 manufactured by NEION Film Coatings Corp.) having a thickness of 5 μm was bonded to each of the upper and lower surfaces of the magnetic layer after the sample piece had been cut out, and then a rectangular magnetic layer having a size of 154 mm×154 mm was cut out. A double-sided tape on each of the upper and lower surfaces of this magnetic layer and a copper foil (conforming to the JIS H3100: 2018 standard, alloy number: C1100R, copper content: 99.90% by mass or more) having a thickness of 12 μm and a rectangular shape of 150 mm×150 mm were bonded to each other.

In this way, a laminate in which the magnetic layer was provided between the two metal layers (copper foils) and the metal layer and the magnetic layer were bonded to each other by the double-sided tape was produced. In the produced laminate, since the magnetic layer is larger than the copper foil as described above, the magnetic layer protrudes from the copper foil by 2 mm in each of the four side directions, and thus the two layers of the copper foil are not in contact with each other. FIG. 7 shows a schematic cross-sectional view of the above-described laminate. It is noted that FIG. 7 and other drawings are schematic diagrams, where the magnitude relationship of dimensions (thickness and the like) of the various layers shown in the drawings is different from the actual magnitude relationship of the dimensions.

### <Coating of Edge Surface of Magnetic Layer>

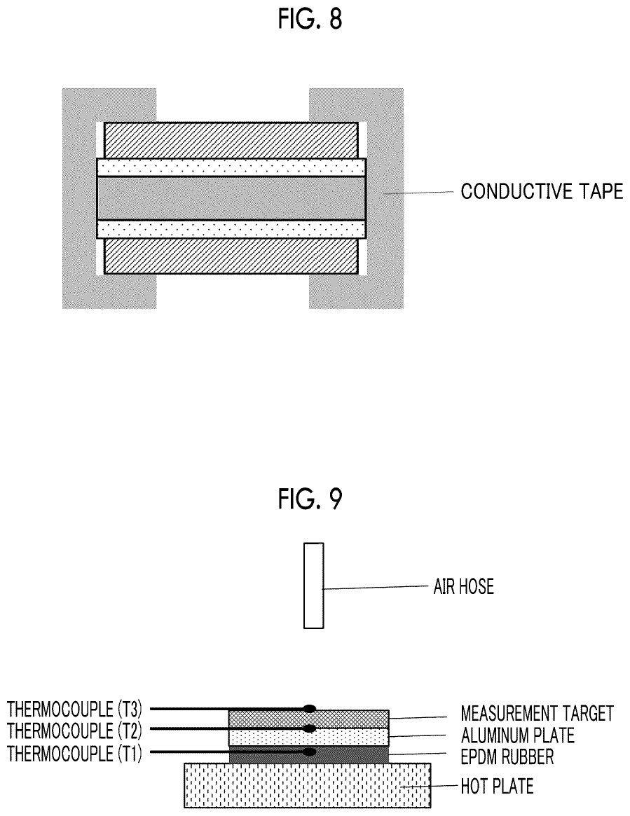

FIG. 8 shows a schematic cross-sectional view of the electromagnetic wave shielding material of Example 1. An electromagnetic wave shielding material of Example 1 was produced according to the following method.

As a coating material, four tape pieces were cut out from a conductive tape (CU-35C manufactured by 3M Japan Limited, thickness: 51 μm). Each tape piece had a length of 154 mm and a width of 10 mm. The four side surfaces of the laminate were covered with these four tape pieces, and the tape pieces were bonded to the laminate as shown in the schematic cross-sectional view of FIG. 8. In this way, an electromagnetic wave shielding material of Example 1, in which all four edge surfaces of the magnetic layer of the laminate were coated with the coating material, was obtained. In the electromagnetic wave shielding material of Example 1, the coating material that coats the edge surface of the magnetic layer is in contact with surfaces of the respective two metal layers (the upper surface of the metal layer on the upper side and the lower surface of the metal layer on the lower side in a case where the surface on the upper side is referred to as an upper surface and the surface on the lower side is referred to as a lower surface in FIG. 8). In addition, the entire surface of each of all the four edge surfaces of the magnetic layer is coated with a coating material.

### <Measurement of Magnetic Permeability of Magnetic Layer>

The magnetic layer was cut into a rectangle of 28 mm×10 mm, the magnetic permeability was measured using a magnetic permeability measuring apparatus (PER01 manufactured by KEYCOM Corporation), and the magnetic permeability was determined as the real part (u′) of the complex specific magnetic permeability at a frequency of 100 KHz. The determined magnetic permeability was 148.

### <Measurement of Electrical Conductivity of Magnetic Layer>

A cylindrical main electrode having a diameter of 30 mm was connected to the negative electrode side of a digital super-insulation resistance meter (TR-811A manufactured by Takeda RIKEN Industries), a ring electrode having an inner diameter of 40 mm and an outer diameter of 50 mm was connected to the positive electrode side thereof, the main electrode was installed on a sample piece of the magnetic layer cut to a rectangle of 60 mm×60 mm, the ring electrode was installed at a position surrounding the main electrode, a voltage of 25 V was applied to both electrodes, and the surface electrical resistivity of the magnetic layer alone was measured. The electrical conductivity of the magnetic layer was calculated from the surface electrical resistivity and the following expression. The calculated electrical conductivity was 1.1×10⁻² S/m. As the thickness, the thickness of the magnetic layer, which had been determined according to the following method, was used.

$$Electrical conductivity [ S / m ] = 1 / ( surface electrical resisitivity [ Ω ] \times thickness [ m ] )$$

### <Acquisition of Cross-Sectional Image of Shielding Material>

Cross-section processing was carried out to expose the cross-section of the shielding material of Example 1 by the following method.

A shielding material cut out to a rectangle of 3 mm×3 mm was embedded in a resin, and a cross section of the shielding material was cut out with an ion milling device (IM4000PLUS manufactured by Hitachi High-Tech Corporation).

The cross-section of the shielding material, which had been exposed in this way, was observed with a scanning electron microscope (SU8220, manufactured by Hitachi High-Tech Corporation) under the conditions of an acceleration voltage of 2 kV and a magnification of 100 times to obtain a backscattered electron image. From the obtained image, the thicknesses of the magnetic layer and the two metal layers were measured at five points based on the scale bar, and the arithmetic averages of the respective thicknesses were denoted as the thickness of the magnetic layer and the thickness of each of the two metal layers. The thickness of the magnetic layer was 30 μm, and the thickness of each of the metal layers was 10 μm. The thickness of each of the various coating materials was determined in the same manner, and it was confirmed that the thickness was the thickness described above.

### <Measurement of Aspect Ratio of Magnetic Particle and Alignment Degree of Flat-Shaped Particle>

In a cross section of the shielding material of Example 1, which had been exposed by the cross-section processing in the same manner as described above, a portion of the magnetic layer was observed with a scanning electron microscope (SU8220, manufactured by Hitachi High-Tech Corporation) under the conditions of an acceleration voltage of 2 kV and a magnification of 1,000 times, thereby obtaining a backscattered electron image.

Using the backscattered electron image acquired as above, the aspect ratio of the magnetic particles was determined according to the method described above, and the flat-shaped particles were specified from the value of the aspect ratio. As a result of determining, as described above, whether or not the magnetic layer contained flat-shaped particles as the magnetic particles, it was determined that the magnetic layer contains flat-shaped particles. Further, as a result of determining the alignment degree of the magnetic particles specified as the flat-shaped particles, according to the method described above, the alignment degree was 13°. In addition, an average value (arithmetic average) of the aspect ratios of all the particles specified as the flat-shaped particles was determined as the aspect ratio of the flat-shaped particles contained in the magnetic layer. The determined aspect ratio was 0.071.

### <Measurement of Thermal Conductivity of Magnetic Layer and Coating Material>

FIG. 9 shows an explanatory view of a measuring method for thermal conductivity.

According to the following method, the thermal conductivity of the sample piece of the magnetic layer, which had been obtained according to the method described above, and the thermal conductivity of each coating material were determined.

A notch having a width of 2 mm was made at the center from one side of an ethylene propylene diene (EPDM) rubber sheet (manufactured by Akitsu Industry Co., Ltd.) having a size of 50 mm×50 mm and a thickness of 1 mm and installed on a hot plate (SCP-125 manufactured by AS ONE Corporation), and then one K thermocouple (referred to as “T1”) attached to a thermocouple thermometer (AD-5602A manufactured by A&D Company, Limited) was inserted into the notch.

An aluminum plate (hereinafter, referred to as “aluminum plate”) (A1050P manufactured by Hikari Co., Ltd.) having a size of 50 mm×50 mm and a thickness of 1 mm was installed on an EPDM rubber sheet, one K thermocouple (referred to as “T2”) attached to a thermocouple thermometer (AD-5602A manufactured by A&D Company, Limited) was installed at a position deviated from the center by 5 mm, and the coating part in the vicinity of the junction point of the thermocouple was fixed to an aluminum plate using a pressure-sensitive adhesive tape (Kapton (registered trademark)) manufactured by Teraoka Seisakusho Co., Ltd.) cut into a rectangle of 10 mm×2 mm.

A measurement target (the sample piece of the magnetic layer, which had been obtained according to the method described above, or each coating material) which had been cut into a rectangle of 50 mm×50 mm was installed on an aluminum plate, one K thermocouple (referred to as “T3”) attached to a thermocouple thermometer (AD-5602A manufactured by A&D Company, Limited) was installed at a position deviated from the center by 5 mm in a direction opposite to the direction of T2, and the coating part in the vicinity of the junction point of the thermocouple was fixed to the measurement target using a pressure-sensitive adhesive tape (Kapton, manufactured by Teraoka Seisakusho Co., Ltd.) cut into a rectangle of 10 mm×2 mm.

Using a pressure-sensitive adhesive tape (Kapton, manufactured by Teraoka Seisakusho Co., Ltd.) cut into a rectangle of 20 mm×2 mm, the measurement target was fixed to a hot plate at a position of 5 mm from each of the four corners of the measurement target.

15 liters per minute of air having a normal temperature (23° C.) was ejected toward the measurement target from an air hose having an inner diameter of 4 mm, which was installed directly above the measurement target, and the set temperature of the hot plate was set to 65° C. and heating was carried out while cooling the center of the measurement target. It was regarded as reaching a steady state at a timing at which a temperature change of each of the thermometers T1, T2, and T3 was 1° C. or lower per minute, and from the temperatures T1 [° C.], T2 [° C.], T3 [° C.] at the respective positions and the thickness d [μm] of the measurement target in the steady state, the thermal conductivity was determined using the following expression, where KAI was the thermal conductivity of the aluminum plate.

$$Thermal conductivity of measurement target = KA 1 \times d \times ( T 2 - T 1 ) / ( 500 \times ( T 3 - T 2 ) )$$

According to the method described above, the thermal conductivity of each of the magnetic layer and the coating material, which were included in the specimen for measuring thermal conductivity, was determined. The thermal conductivity of the coating material was obtained as a relative value, where the thermal conductivity of the magnetic layer was set to 1.0, and was 1.9.

### <Measurement of Resistivity of Coating Material>

The resistivity of the conductive tape (CU-35C manufactured by 3M Japan Limited) which had been used as the coating material described above was measured according to the following method.

Two probes of a digital multimeter (KU-2608 manufactured by KAISE CORPORATION) were brought into contact with a surface of the conductive tape cut into a size of 20 mm×5 mm on the pressure-sensitive adhesive layer side to measure a resistance value R. One probe was brought into contact with a center position in the width direction by 5 mm inside from one end in the longitudinal direction, and the other probe was brought into contact with a center position in the width direction by 5 mm inside from the other end in the longitudinal direction. The distance L between electrodes in the digital multimeter used here is 0.01 m. A cross-sectional area S of the measurement target, which is determined from the “thickness×width”, is 2.55×10⁻⁵ m².

The resistivity ρ was determined from the resistance value R, the distance L between electrodes, and the cross-sectional area S of the measurement target, according to the following expression, and was 0.00051 Ω·m.

$$Resistivity ρ ( unit : Ω \cdot m ) = RS / L$$

### <Measurement of Resistance Value Between Metal Layers>

For the electromagnetic wave shielding material of Example 1, one probe of a digital multimeter (KU-2608 manufactured by KAISE CORPORATION) was brought into contact with the center of the outer surface of one metal layer of the electromagnetic wave shielding material, and the other probe was brought into contact with the center of the outer surface of the metal layer on the opposite side to measure the resistance value, and the resistance value was 0.2Ω.

### Examples 2 and 3 and Comparative Example 1

An electromagnetic wave shielding material was produced according to the method described for Example 1, except that the defoaming time of the coating liquid (composition for forming a magnetic layer) was changed as shown in Table 1.

### Comparative Example 2

An electromagnetic wave shielding material was produced according to the method described for Example 1, except that the defoaming treatment of the coating liquid (composition for forming a magnetic layer) was not performed.

### Example 4

In order to suppress the generation of bubbles in the coating liquid in the shaking type stirring, 500 g of alumina balls having a diameter of 1 mm were charged into the plastic bottle, and the components of the coating liquid were filled into the plastic bottle without forming a gap in the bottle by air, and the plastic bottle was subjected to shaking type stirring for 1 hour with a shaking type stirrer. An electromagnetic wave shielding material was produced by the method described for Example 1, except for the above-described points. The shaking type stirring method of the coating liquid in Example 4 is referred to as “B”. On the other hand, in Examples other than Example 4 and Comparative Examples, the shaking type stirring was performed in a state where air portions and coating liquid portions coexisted in the plastic bottle without charging the alumina balls into the plastic bottle. The shaking type stirring method of the coating liquid in Examples other than Example 4 and Comparative Examples is referred to as “A”.

### [Measurement of Scratch Cross-Sectional Area of Magnetic Layer]

The scratch cross-sectional area of the magnetic layer of each of the electromagnetic wave shielding materials of Examples and Comparative Examples was obtained, according to the method described above. As the ion milling device, IM4000PLUS manufactured by Hitachi High-Tech Corporation was used, as the surface shape measuring device, TriboIndenter TI-950 manufactured by Bruker Corporation was used, and as the image analysis software, ImageJ was used.

### [Evaluation of Electromagnetic Wave Shielding Performance (KEC Method)]

Each of the electromagnetic wave shielding materials (size: 150 mm×150 mm) of Examples and Comparative Examples was subjected to a vibration application treatment by the following method.

A vibration testing machine and the electromagnetic wave shielding material were disposed in a chamber, and a vibration application treatment of applying vibration by a sine wave having a frequency of 25 Hz and an amplitude of 1.5 mm was performed for 72 hours. The atmospheric temperature during the vibration application treatment was kept constant at 40° C., and the vibration application treatment was performed for 72 hours.

The electromagnetic wave shielding performance of each electromagnetic wave shielding material was evaluated by the following method before and after the vibration application treatment.

An electromagnetic wave shielding material was installed between antennas of a KEC method evaluation device including a signal generator, an amplifier, a pair of magnetic field antennas, and a spectrum analyzer, and at a frequency of 100 kHz to 1 GHz, a ratio (unit: decibel (dB)) of the intensity of the received signal in a case where the electromagnetic wave shielding material was not present to the intensity of the received signal in a case where the electromagnetic wave shielding material was present was determined and denoted as the shielding performance. The operation was carried out for the magnetic field antenna to obtain the magnetic field wave shielding performance. KEC is an abbreviation for Kansai Electronic Industry Development Center.

The above results are shown in Table 1.

TABLE 1

| | | | | Scratch cross-sectional | | Shielding performance |
|---|---|---|---|---|---|---|
| | Coating liquid | | Shaking type | area of magnetic layer | Initial shielding | after vibration |
| | defoaming time | | stirring method | (μm²) | performance (dB) | application treatment |
| Example 1 | 5 | minutes | A | 1.25 | 14.8 | 13.5 |
| Example 2 | 10 | minutes | A | 0.42 | 14.9 | 14.7 |
| Example 3 | 20 | minutes | A | 0.08 | 15.0 | 13.9 |
| Example 4 | 5 | minutes | B | 0.23 | 14.7 | 14.6 |
| Comparative | 40 | minutes | A | 0.03 | 15.0 | 9.8 |
| Example 1 | | | | | | |

| | | | | | |
|---|---|---|---|---|---|
| Comparative | None | A | 1.63 | 14.5 | 8.9 |
| Example 2 | | | | | |

From the results shown in Table 1, it can be confirmed that, in the electromagnetic wave shielding materials of Examples 1 to 4, the decrease in electromagnetic wave shielding performance after being subjected to vibration is suppressed as compared with the electromagnetic wave shielding materials of Comparative Examples 1 and 2.

One aspect of the present invention is useful in the technical fields of various electronic components and various electronic apparatuses.

What is claimed is:

1. An electromagnetic wave shielding material comprising:
a magnetic layer containing magnetic particles,
wherein a scratch cross-sectional area of the magnetic layer is 0.08 μm² or more and 1.25 μm² or less.

2. The electromagnetic wave shielding material according to claim 1,
wherein the magnetic layer is provided between two metal layers.

3. The electromagnetic wave shielding material according to claim 2, further comprising:
one or more layers containing a resin, provided between the magnetic layer sandwiched between the two metal layers and one or both of the two metal layers.

4. The electromagnetic wave shielding material according to claim 1,
wherein the magnetic layer further contains a resin.

5. The electromagnetic wave shielding material according to claim 1,
wherein the scratch cross-sectional area of the magnetic layer is 0.10 μm² or more and 1.00 μm² or less.

6. The electromagnetic wave shielding material according to claim 1,
wherein the magnetic layer is provided between two metal layers,
the magnetic layer further contains a resin, and
the scratch cross-sectional area of the magnetic layer is 0.10 μm² or more and 1.00 μm² or less.

7. The electromagnetic wave shielding material according to claim 6, further comprising:
one or more layers containing a resin, provided between the magnetic layer sandwiched between the two metal layers and one or both of the two metal layers.

8. An electronic component comprising:
the electromagnetic wave shielding material according to claim 1.

9. An electronic apparatus comprising:
the electromagnetic wave shielding material according to claim 1.
